(19) United States
(12) Patent Application Publication
(10) Pub. No.: US 2021/0280657 A1
(43) Pub. Date: Sep. 9, 2021

(54) ORGANIC LIGHT EMITTING DIODE DISPLAY PANEL AND ELECTRONIC DEVICE

(71) Applicant: TCL CHINA STAR OPTOELECTRONICS TECHNOLOGY CO., LTD., Shenzhen, Guangdong (CN)

(72) Inventor: Hui Huang, Shenzhen (CN)

(21) Appl. No.: 16/617,294

(22) PCT Filed: Jun. 28, 2019
(86) PCT No.: PCT/CN2019/093688

§ 371 Date: Nov. 26, 2019

(30) Foreign Application Priority Data
Apr. 30, 2019 (CN) 201910362372.1

(51) Int. Cl. H01L 27/32; H01L 51/52

(52) U.S. Cl. CPC H01L 27/3272; H01L 51/5268; H01L 27/3246

(57) ABSTRACT

An organic light emitting diode (OLED) display panel and an electronic device. The OLED display panel includes a substrate, a thin film transistor layer, and a light emitting structure. The light emitting structure includes an anode, a pixel defining layer, a light emitting layer, and a cathode. The light emitting structure further includes a photoresist layer between the anode and the light emitting layer.

### BACKGROUND OF INVENTION

### Field of Invention

The present invention relates to the field of electronic display, and in particular, to an organic light emitting diode (OLED) display panel and an electronic device.

### Description of Prior Art

Thin film transistors (TFTs) are an important part of display panels. TFTs made of amorphous silicon (A-Si) are easy to produce while cost less, and are widely used in display panels.

Amorphous silicon has a forbidden bandgap of 1.7 eV, which is particularly sensitive to light. When an illumination energy of light is greater than the forbidden bandgap of amorphous silicon, electrons will transition from a conduction band to a valence band, forming a current channel in the amorphous silicon. A ratio of a conductance of amorphous silicon in which an electronic transition occurs to a conductance of amorphous silicon in which no electronic transition occurs is up to 10⁵. The change in conductance can cause TFTs to be difficult to turn off or even fail, affecting the performance of the TFTs.

### Technical Problems

In a working environment of a TFT device, there is illumination from the backlight and from the outside. Various types of reflected light and scattered light will affect electrical properties of the TFT. In an organic light emitting diode (OLED) display, light emitted from a light emitting layer passes through respective layers between an active region and the light emitting material to reach the active region, seriously affecting the electrical properties of the amorphous silicon in the active region. Therefore, it is necessary to block the light emitted by the light emitting structure to eliminate the influence of illumination on the performance of the TFT and improve the working stability of the TFT.

### SUMMARY OF INVENTION

The present application provides an organic light emitting diode (OLED) display panel and an electronic device capable of eliminating the negative influence of light emitted by a light emitting structure on amorphous silicon in a thin film transistor.

In order to solve the above problems, the present application provides an OLED display panel, wherein the OLED display panel comprises:

a substrate;

a thin film transistor layer disposed above the substrate; and

a light emitting structure, the light emitting structure comprising:
an anode disposed above the thin film transistor layer and electrically connected to the thin film transistor layer;
a pixel defining layer covering the anode and having an opening exposing the anode;
a light emitting layer disposed in the opening, electrically connected to the anode;
a cathode covering the light emitting layer and electrically connected to the light emitting layer;

wherein the light emitting structure further comprises a photoresist layer disposed between the anode and the light emitting layer.

According to one aspect of the application, wherein the photoresist layer comprises scattering particles uniformly distributed on a surface of the anode in the opening.

According to one aspect of the application, wherein the scattering particles have a same shape and size;

wherein the scattering particles are spherical or regular polyhedron.

According to one aspect of the application, wherein a surface of each of the scattering particles is a diffuse reflection structure.

According to one aspect of the application, wherein a material forming the scattering particles is a metal oxide comprising one or more of titanium oxide, magnesium oxide, and zinc oxide.

According to one aspect of the application, wherein the photoresist layer is a light shielding metal layer.

According to one aspect of the application, wherein a surface of the light shielding metal layer is a mirror structure.

According to one aspect of the application, wherein the surface of the light shielding metal layer is disposed with convex structures distributed continuously, and each of the convex structure is a conical structure or a regular tetrahedral structure.

According to one aspect of the application, wherein the material forming the light shielding metal layer is silver or aluminum.

The present application further provides an electronic device comprising an OLED display panel, wherein the OLED display panel comprises:

a substrate;

a thin film transistor layer disposed above the substrate; and

a light emitting structure, the light emitting structure comprising:
an anode disposed above the thin film transistor layer and electrically connected to the thin film transistor layer;
a pixel defining layer covering the anode and having an opening exposing the anode;
a light emitting layer disposed in the opening, electrically connected to the anode;
a cathode covering the light emitting layer and electrically connected to the light emitting layer;

wherein the light emitting structure further comprises a photoresist layer disposed between the anode and the light emitting layer.

The electronic device according to claim 1, wherein the photoresist layer comprises scattering particles uniformly distributed on a surface of the anode in the opening.

According to one aspect of the application, wherein the scattering particles have a same shape and size;

wherein the scattering particles are spherical or regular polyhedron.

According to one aspect of the application, wherein a surface of each of the scattering particles is a diffuse reflection structure.

According to one aspect of the application, wherein a material forming the scattering particles is a metal oxide comprising one or more of titanium oxide, magnesium oxide, and zinc oxide.

According to one aspect of the application, wherein the photoresist layer is a light shielding metal layer.

According to one aspect of the application, wherein a surface of the light shielding metal layer is a mirror structure.

According to one aspect of the application, wherein the surface of the light shielding metal layer is disposed with convex structures distributed continuously, and each of the convex structure is a conical structure or a regular tetrahedral structure.

According to one aspect of the application, wherein the material forming the light shielding metal layer is silver or aluminum.

Beneficial Effects

The present application provides a photoresist layer in the light emitting layer of an organic light emitting diode (OLED) display panel. The photoresist layer is located between a light emitting material and an anode, and can effectively absorb light emitted by the light emitting material and into a thin film transistor layer under the light emitting material. Thereby, negative influence of the light emitted by the light emitting material on an amorphous silicon in the thin film transistor is effectively avoided, and the threshold voltage drift is avoided as well.

### BRIEF DESCRIPTION OF DRAWINGS

FIG. 1 is a structural diagram of an organic light emitting diode (OLED) display panel in the prior art.

FIG. 2 is a structural diagram of a photoresist layer in an OLED display panel according to an embodiment of the present application.

FIG. 3 is a structural diagram of an OLED display panel in an embodiment of the present application.

FIG. 4 is a structural diagram of an OLED display panel in a second embodiment of the present application.

FIG. 5 is a structural diagram of an OLED display panel in a third embodiment of the present application.

### DETAILED DESCRIPTION OF PREFERRED EMBODIMENTS

Description of following embodiment, with reference to accompanying drawings, is used to exemplify specific embodiments which may be carried out in the present disclosure. Directional terms mentioned in the present disclosure, such as “top”, “bottom”, “front”, “back”, “left”, “right”, “inside”, “outside”, “side”, etc., are only used with reference to orientation of the accompanying drawings. Therefore, the directional terms are intended to illustrate, but not to limit, the present disclosure. In the drawings, components having similar structures are denoted by same numerals.

First, the prior art will be briefly described. Referring to FIG. 1, FIG. 1 is a structural diagram of an organic light emitting diode (OLED) display panel in the prior art. The OLED display panel of the prior art includes a substrate 110, a thin film transistor layer, and a light emitting structure.

The thin film transistor layer is located above the substrate 110 and includes an active region, a gate dielectric layer 130, a gate metal layer 140, an interlayer dielectric layer 150, a source/drain metal layer 160, and a planarization layer 170.

The active region includes a channel region 120 and source/drain regions 122 on both sides of the channel region 120.

The light emitting structure includes an anode 182 electrically connected to the source/drain metal layer 160 through a via hole, a pixel defining layer 190 covering the planarization layer 170 and having an opening exposing the anode 182, a light emitting layer 184 disposed on the anode 182, and a cathode 186 covering the light emitting layer 184.

Because the anode 182 and the cathode 186 are made of a transparent conductive material, light emitted from the light emitting layer 184 can easily pass through the dielectric layer in the thin film transistor layer to reach the active region. Because amorphous silicon is particularly sensitive to light, when an illumination energy of light is greater than a forbidden bandgap of amorphous silicon, electrons will transition from a conduction band to a valence band, forming a current channel in the amorphous silicon. Therefore, a thin film transistor layer made of amorphous silicon is easily affected by light in the light emitting layer 184 to cause device failure.

In order to solve the above problems, the present application provides an OLED display panel and an electronic device capable of eliminating the negative influence of light emitted by a light emitting structure on amorphous silicon in a thin film transistor.

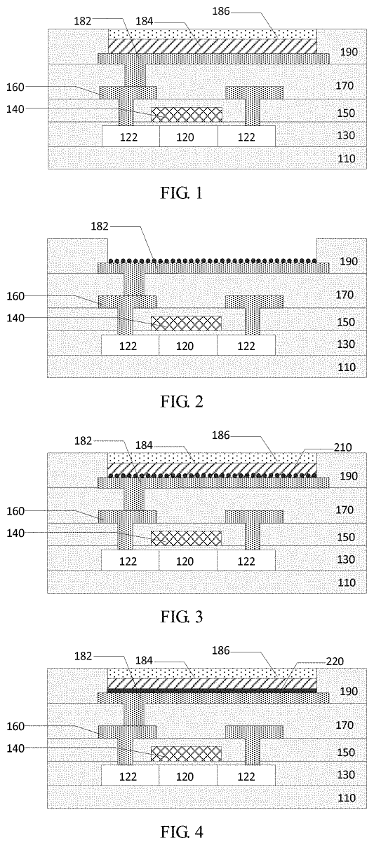

The present application will be described in detail below with reference to the accompanying drawings. Referring to FIG. 2 and FIG. 3, FIG. 2 is a structural diagram of a photoresist layer in an OLED display panel according to an embodiment of the present application, FIG. 3 is a structural diagram of an OLED display panel in an embodiment of the present application.

An OLED display panel provided by the present application includes a substrate 110, a thin film transistor layer, and a light emitting structure.

The thin film transistor layer is located above the substrate 110 and includes an active region, a gate dielectric layer 130, a gate metal layer 140, an interlayer dielectric layer 150, a source/drain metal layer 160, and a planarization layer 170. The active region includes a channel region 120 and source/drain regions 122 on both sides of the channel region 120.

The light emitting structure is located above the thin film transistor layer and includes an anode 182 located above the thin film transistor layer and is electrically connected to the thin film transistor layer, a pixel defining layer 190 covering the anode 182 and having an opening exposing the anode 182, a light emitting layer 184 located in the opening and is electrically connected to the anode 182, a cathode 186 covering and electrically connecting to the light emitting layer 184.

The light emitting structure further includes a photoresist layer 210 between the anode 182 and the light emitting layer 184. The photoresist layer 210 is configured to absorb light emitted by the light emitting layer 184 to protect amorphous silicon in the active region in the thin film transistor from being affected by the light emitting layer.

In the present embodiment, the photoresist layer 210 includes scattering particles uniformly distributed on a surface of the anode 182 in the opening. The uniformly distributed scattering particles can effectively refract light emitted from the light emitting layer 184 to prevent light from entering the thin film transistor layer under the anode 182.

In this embodiment, the scattering particles have a same shape and size, wherein the scattering particles are spherical or regular polyhedron. To facilitate process implementation, the scattering particles have a same shape and size. Preferably, the scattering particles can be spherical, which is advantageous for the process. Preferably, the scattering particles can be a regular polyhedron, which can effectively reflect light and have a good the photoresist effect.

In this embodiment, a surface of the scattering particles is a diffuse reflection structure. The diffuse reflective structure includes a rough surface structure. The diffuse reflection structure can further increase the absorption of light by the scattering particles and improve the photoresist efficiency.

In the present embodiment, the material forming the scattering particles is a metal oxide including one or more of titanium oxide, magnesium oxide, and zinc oxide.

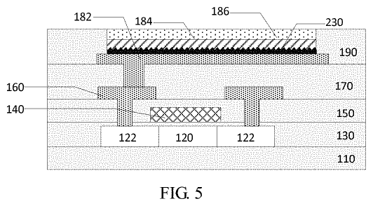

Referring to FIG. 4 and FIG. 5, FIG. 4 is a structural diagram of an OLED display panel in a second embodiment of the present application, FIG. 5 is a structural diagram of an OLED display panel in a third embodiment of the present application.

In another embodiment of the present application, the photoresist layer 210 is a light shielding metal layer, and a surface of the light shielding metal layer is a mirror structure. The light shielding metal having a mirror structure which can effectively reflect light emitted by the light emitting layer 184 to a light emitting surface. Not only efficiency of the photoresist layer is enhanced, but also the light emitting intensity of the pixel points is increased.

The surface of the light shielding metal layer is disposed with convex structures distributed continuously, and each of the convex structure is a conical structure or a regular tetrahedral structure, the material forming the light shielding metal layer is silver or aluminum.

Accordingly, the present application also provides an electronic device including the OLED display panel as described above.

The present application provides a photoresist layer in the light emitting layer of an organic light emitting diode (OLED) display panel. The photoresist layer is located between a light emitting material and an anode, and can effectively absorb light emitted by the light emitting material and into a thin film transistor layer under the light emitting material. Thereby, negative influence of the light emitted by the light emitting material on an amorphous silicon in the thin film transistor is effectively avoided, and the threshold voltage drift is avoided as well.

As is understood by persons skilled in the art, the foregoing preferred embodiments of the present disclosure are illustrative rather than limiting of the present disclosure. It is intended that they cover various modifications and that similar arrangements be included in the spirit and scope of the present disclosure, the scope of which should be accorded the broadest interpretation so as to encompass all such modifications and similar structures.

What is claimed is:

1. An organic light emitting diode (OLED) display panel, wherein the OLED display panel comprises:
a substrate;
a thin film transistor layer disposed above the substrate; and
a light emitting structure, the light emitting structure comprising:
an anode disposed above the thin film transistor layer and electrically connected to the thin film transistor layer;
a pixel defining layer covering the anode and having an opening exposing the anode;
a light emitting layer disposed in the opening, electrically connected to the anode;
a cathode covering the light emitting layer and electrically connected to the light emitting layer;
wherein the light emitting structure further comprises a photoresist layer disposed between the anode and the light emitting layer.

2. The OLED display panel according to claim 1, wherein the photoresist layer comprises scattering particles uniformly distributed on a surface of the anode in the opening.

3. The OLED display panel according to claim 2, wherein the scattering particles have a same shape and size;
wherein the scattering particles are spherical or regular polyhedron.

4. The OLED display panel according to claim 3, wherein a surface of each of the scattering particles is a diffuse reflection structure.

5. The OLED display panel according to claim 3, wherein a material forming the scattering particles is a metal oxide comprising one or more of titanium oxide, magnesium oxide, and zinc oxide.

6. The OLED display panel according to claim 1, wherein the photoresist layer is a light shielding metal layer.

7. The OLED display panel according to claim 6, wherein a surface of the light shielding metal layer is a mirror structure.

8. The OLED display panel according to claim 7, wherein the surface of the light shielding metal layer is disposed with convex structures distributed continuously, and each of the convex structure is a conical structure or a regular tetrahedral structure.

9. The OLED display panel according to claim 6, wherein the material forming the light shielding metal layer is silver or aluminum.

10. An electronic device comprising an organic light emitting diode (OLED) display panel, wherein the OLED display panel comprises:
a substrate;
a thin film transistor layer disposed above the substrate; and
a light emitting structure, the light emitting structure comprising:
an anode disposed above the thin film transistor layer and electrically connected to the thin film transistor layer;
a pixel defining layer covering the anode and having an opening exposing the anode;
a light emitting layer disposed in the opening, electrically connected to the anode;
a cathode covering the light emitting layer and electrically connected to the light emitting layer;
wherein the light emitting structure further comprises a photoresist layer disposed between the anode and the light emitting layer.

11. The electronic device according to claim 10, wherein the photoresist layer comprises scattering particles uniformly distributed on a surface of the anode in the opening.

12. The electronic device according to claim 11, wherein the scattering particles have a same shape and size;
wherein the scattering particles are spherical or regular polyhedron.

13. The electronic device according to claim 12, wherein a surface of each of the scattering particles is a diffuse reflection structure.

14. The electronic device according to claim 12, wherein a material forming the scattering particles is a metal oxide comprising one or more of titanium oxide, magnesium oxide, and zinc oxide.

15. The electronic device according to claim 10, wherein the photoresist layer is a light shielding metal layer.

16. The electronic device according to claim 15, wherein a surface of the light shielding metal layer is a mirror structure.

17. The electronic device according to claim 16, wherein the surface of the light shielding metal layer is disposed with convex structures distributed continuously, and each of the convex structure is a conical structure or a regular tetrahedral structure.

18. The electronic device according to claim 15, wherein the material forming the light shielding metal layer is silver or aluminum.
